(19) United States
(12) Patent Application Publication
(10) Pub. No.: US 2026/0246395 A1
(43) Pub. Date: Aug. 20, 2026

(54) POWER CONVERTER

(71) Applicant: KABUSHIKI KAISHA TOYOTA JIDOSHOKKI, Aichi (JP)

(72) Inventor: Ryo TAKEMURA, Kariya-shi (JP)

(73) Assignee: KABUSHIKI KAISHA TOYOTA JIDOSHOKKI, Aichi (JP)

(21) Appl. No.: 19/539,805

(22) Filed: Feb. 13, 2026

(30) Foreign Application Priority Data
Feb. 17, 2025 (JP) 2025-023391

(51) Int. Cl. H02M 7/48; H02M 7/00; H02M 7/44; H02M 7/537

(52) U.S. Cl. CPC H02M 7/48; H02M 7/003; H02M 7/44; H02M 7/537

(57) ABSTRACT

A power converter is mounted on a mounting target by a mounting device. The power converter includes a circuit board on which electric components are mounted, a board support member, a pressing member having a fixed portion and a pressing portion that presses at least one of a component used in the power converter or the electric components against the circuit board, and held portions that are each engaged with a holding arm of the mounting device. At least one of the held portions is an extending portion. The board support member has a fixing portion to which the pressing portion is fixed. The extending portion is located closer to an edge portion of the board support member than the fixing portion.

### CROSS-REFERENCE OF THE RELATED APPLICATION

This application claims priority to Japanese Patent Application No. 2025-023391 filed on February 17, 2025, the entire disclosure of which is incorporated herein by reference.

### BACKGROUND ART

The present disclosure relates to a power converter.

An insulated power converter is disclosed in Japanese Patent Application Publication No. 2017-79545. The insulated power converter includes a circuit board, an input terminal provided on the circuit board, an output terminal provided on the circuit board, a primary winding, and a secondary winding with a different number of turns of the primary winding. The insulated power converter has a transformer provided on the circuit board, a pattern having a first pattern formed between the input terminal and the primary winding, and a second pattern formed between the output terminal and the secondary winding.

A power converter may include a board support member having a plate shape for supporting a circuit board on which an electric component is mounted. A configuration of the power converter in which the circuit board is supported by an aluminum plate is disclosed in the Publication. Such a power converter is moved to a mounting position with the board support member being held. When the power converter is mounted in a case, a holding arm of a mounting device is hooked onto a held portion of the board support member in order to hold the board support member. However, since a wall of the case and other components obstruct the holding arm extending from a side of the board support member, the power converter needs to be hung on the holding arm. The circuit board is placed on an upper side of the board support member, and thus, the held portion is formed to hook the holding arm that avoids the circuit board and extends from above the board support member. In this case, as a region occupied by the held portion in the case increases, a space in the case for placing the circuit board decreases. The held portion, which is only used for mounting the power converter, is preferably designed to occupy as little space as possible. Thus, a space efficiency in the case as a mounting target may be improved.

The present disclosure is directed to providing a power converter in which a space efficiency in a mounting target is improved.

### SUMMARY

According to one aspect of the present disclosure, there is provided a power converter mounted on a mounting target by a mounting device, the power converter including a circuit board on which a plurality of electric components is mounted, a board support member that supports the circuit board, a pressing member having a fixed portion that is fixed to the board support member and a pressing portion that presses at least one of a component used in the power converter or the plurality of the electric components against the circuit board, and a plurality of held portions that is each engaged with a holding arm of the mounting device. At least one of the plurality of the held portions is an extending portion that is formed in the pressing member. The board support member has a fixing portion to which the pressing portion is fixed. The extending portion is located closer to an edge portion of the board support member than the fixing portion.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a plan view illustrating a power converter according to an embodiment of the present disclosure;

FIG. 2 is a cross-sectional view taken along a line II-II in FIG. 1;

FIG. 3 is an enlarged perspective view illustrating a region including a pressing member in the power converter;

FIG. 4 is a schematic plan view illustrating a plurality of held portions and a center of gravity of the power converter;

FIG. 5 is a plan view illustrating a power converter according to a comparative example;

FIG. 6 is a cross-sectional view taken along a line VI-VI in FIG. 5; and

FIG. 7 is an enlarged cross-sectional view illustrating a power converter according to a modification of the present disclosure.

### DETAILED DESCRIPTION OF THE EMBODIMENTS

The following will describe an embodiment according to the present disclosure with reference to the accompanying drawings. In the accompanying drawings, identical or equivalent components are denoted by the same reference numerals, and redundant description will be omitted.

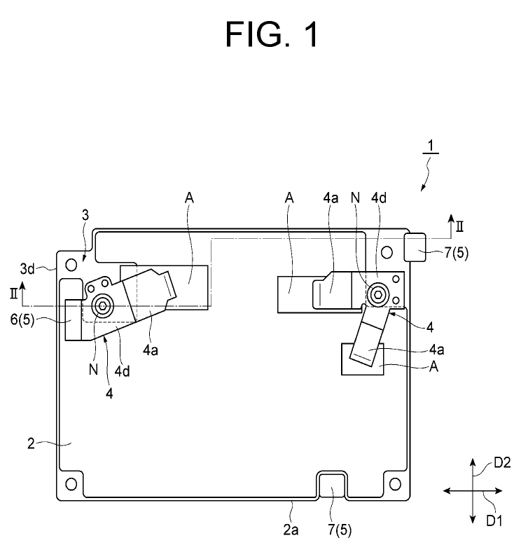

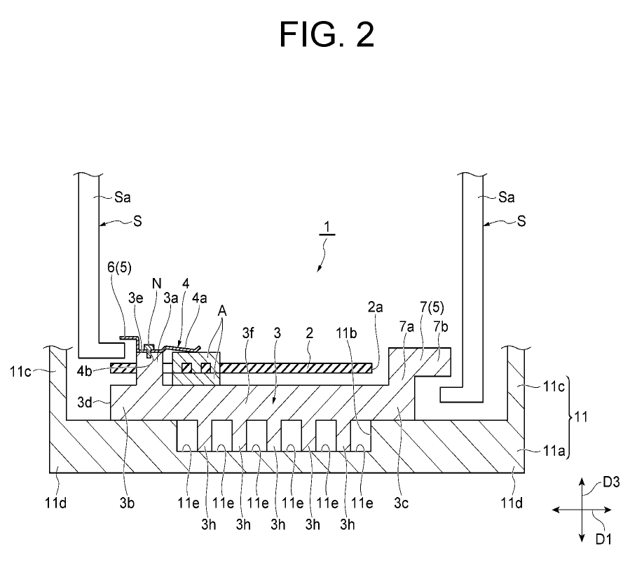

FIG. 1 is a plan view illustrating a power converter according to the embodiment of the present disclosure. In FIG. 1, a circuit board 2 (described later) is illustrated only in outline. FIG. 2 is a cross-sectional view taken along a line II-II in FIG. 1. FIG. 2 schematically illustrates a cross-section of the power converter 1 taken along both a longitudinal direction and a vertical direction of the power converter 1.

The power converter 1 is mounted on a mounting target by a mounting device S. The mounting target is a case 11 of a power supply that is mounted on a vehicle including a hybrid vehicle and an electric vehicle. The mounting device S is a device used for mounting the power converter 1 on the mounting target.

The power converter 1 is a DC/DC converter, for example. The power converter 1 includes the circuit board 2, a board support member 3, a plurality of pressing members 4 (two pressing members 4 in the present embodiment), and held portions 5.

A plurality of electric components A, which is not illustrated, is mounted on the circuit board 2 by soldering. The electric components A may be components that are not mounted on the circuit board 2 and fixed to the circuit board 2 by a method other than soldering. Examples of the electric components A that are not mounted on the circuit board 2 include a core of a transformer or a reactor illustrated in FIG. 2. The electric components A that include the core of the transformer or the reactor correspond to the component used in the power converter 1 in the present disclosure.

In the following description, a longitudinal direction of the circuit board 2 is defined as a first direction D1, a width direction of the circuit board 2 is defined as a second direction D2, and a direction perpendicular to both the first direction D1 and the second direction D2 is defined as a third direction D3. Note that these directions are used for ease of explanation, and locations or directions of components are not limited thereto. The second direction D2 intersects with the first direction D1. The third direction D3 is a thickness direction of the circuit board 2.

A pair of the electric components A that forms the core of the transformer is, for example, placed close to an edge portion 2a of the circuit board 2. For example, the electric components A are each placed on a front surface and a back surface of the circuit board 2. The pair of the electric components A has magnetic legs passing through holes 2b formed in the circuit board 2. The electric components A are arranged in the third direction D3 with the circuit board 2 interposed therebetween.

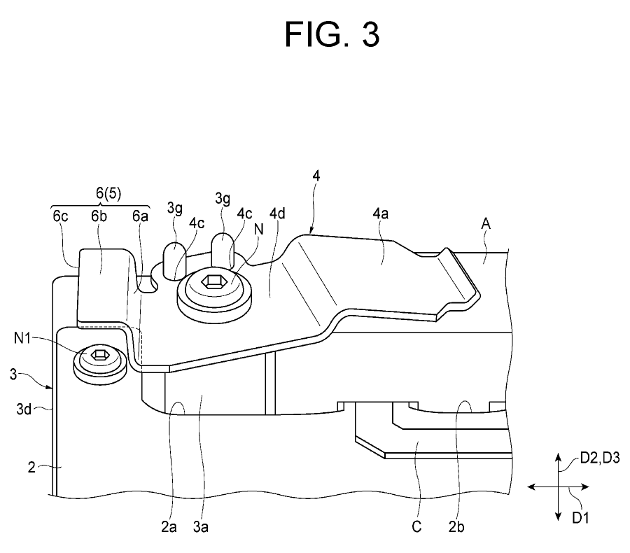

Although not illustrated, an electronic component such as a switching element, a heating element, a winding of the transformer or the reactor, and the like may be provided on the circuit board 2. In addition, as illustrated in FIG. 3 (described later), a winding C of the transformer (copper plate) may be disposed around one of the holes 2b of the circuit board 2 through which the magnetic legs of the electric components A that form the core of the transformer pass. The winding of the transformer may be disposed in an inner layer of the circuit board 2 or on the back surface thereof.

The board support member 3 supports the circuit board 2. The board support member 3 is made of metal such as aluminum. The board support member 3 is a die-cast plate, for example. The board support member 3 is sometimes referred to as a base plate.

The board support member 3 has a base portion 3f and a plurality of fixing portions 3a. The base portion 3f is located below the circuit board 2 (on a side closer to the case 11 relative to the circuit board 2 in the third direction D3). The base portion 3f extends along the circuit board 2. For example, a thickness of the base portion 3f is greater than the thickness of the circuit board 2. A plurality of bosses, which is not illustrated, protrudes from the base portion 3f toward the circuit board 2, and the circuit board 2 is fixed to the board support member 3 with screws screwed into the bosses.

A fastening portion 4d (described later) as a fixed portion of each of the pressing members 4 is fixed to its associated one of the fixing portions 3a. The fixing portions 3a are each located close to an edge portion 3d of the board support member 3. One of the fixing portions 3a is located at a first end portion 3b of the board support member 3 in the first direction D1. The fixing portions 3a each protrude from an upper surface of the base portion 3f. The fixing portions 3a are each adjacent to the edge portion 2a of the circuit board 2.

The fixing portions 3a each extend above the circuit board 2 (in a direction opposite to a bottom portion 11a of the case 11, which will be described later, along the third direction D3) from the base portion 3f. When viewed in the third direction D3, a portion of the circuit board 2 that overlaps with each of the fixing portions 3a is cut out. An upper end 3e of each of the fixing portions 3a is in contact with its associated one of the pressing members 4.

The fixing portions 3a each have a tubular shape, for example. The fixing portions 3a are bosses, for example. A thread groove, which is not illustrated, is formed on an inner surface of each of the fixing portions 3a that has the tubular shape so as to allow a thread N to be screwed. The board support member 3 and each of the pressing members 4 are fastened to each other with the thread N.

The power converter 1 may be accommodated in the case 11. The case 11 has a box shape. The case 11 has a bottom portion 11a and a side wall portion 11c.

The bottom portion 11a extends along the circuit board 2 and the board support member 3. The bottom portion 11a extends in the first direction D1 and the second direction D2. For example, a thickness of the bottom portion 11a is greater than a thickness of the base portion 3f of the board support member 3. On the bottom portion 11a of the case 11, a circuit board or a component including an electric component such as the reactor may be provided other than the power converter 1.

A recess portion 11b is formed in an upper portion of the bottom portion 11a of the case 11. The recess portion 11b is recessed in a direction away from the board support member 3 along the third direction D3. The recess portion 11b faces the board support member 3.

A plurality of protruding portions 3h is formed in a lower portion of the board support member 3 (a portion that faces the recess portion 11b). The protruding portions 3h each have a plate shape and extend in the second direction D2. The protruding portions 3h protrude from the base portion 3f toward the recess portion 11b. The protruding portions 3h are arranged in the first direction D1. When the board support member 3 is accommodated in the case 11, grooves 11e are formed of the recess portion 11b of the case 11 and the protruding portions 3h of the board support member 3.

The grooves 11e serve as passages through which refrigerant flows to cool the power converter 1. The grooves 11e serve as water passages, for example. A shape of the grooves 11e is not particularly limited. For example, the grooves 11e may extend in the first direction D1 or in the second direction D2. The protruding portions 3h are formed so that the protruding portions 3h extend from the base portion 3f of the board support member 3 to form the grooves 11e. This increases an area of the board support member 3 that is in contact with refrigerant, so that heat in the board support member 3 is easily transferred to the refrigerant. Note that the protruding portions 3h each need not have a plate shape and may have a pin shape or the like.

The side wall portion 11c extends upward (in a direction opposite to the direction in which the recess portion 11b is recessed along the third direction D3) from the bottom portion 11a. The side wall portion 11c extends from the bottom portion 11a in the third direction D3. The side wall portion 11c has a rectangular tube shape. The side wall portion 11c is located in both end portions 11d of the bottom portion 11a in the first direction D1 and both end portions, which are not illustrated, in the second direction D2. The side wall portion 11c surrounds the power converter 1.

The mounting device S has a plurality of holding arms Sa. The holding arms Sa of the mounting device S hold and move the power converter 1 in order to mount the power converter 1 on the case 11. The power converter 1 is hung on the holding arms Sa. The holding arms Sa are movable in three-axial directions, for example.

The holding arms Sa each have an L-shape, for example. A distal end portion of each of the holding arms Sa is bent toward a center portion of the power converter 1. With this configuration, the holding arms Sa may easily hold the power converter 1.

The held portions 5 are portions on which the holding arms Sa are hung, when the power converter 1 is mounted on the case 11. The held portions 5 are engaged with the holding arms Sa of the mounting device S. The number of the holding arms Sa is the same as the number of the held portions 5, for example.

The power converter 1 includes a plurality of the held portions 5 (three held portions 5 in the present embodiment). Some of the held portions 5 are bending portions 7 formed in the board support member 3. A plurality of the bending portions 7 (two bending portions 7 in the present embodiment) is formed in the board support member 3.

In the present embodiment, one of the two bending portions 7 formed in the board support member 3 is located on one side (at a second end portion 3c) in the longitudinal direction (the first direction D1) of the circuit board 2, and the other of the two bending portions 7 is located on one side in a width direction (the second direction D2) of the circuit board 2. The one of the two bending portions 7 is illustrated in FIG. 2.

The bending portions 7 are formed integrally with the board support member 3. The bending portions 7 are located close to the edge portion 2a of the circuit board 2. The bending portions 7 extend above the circuit board 2. When viewed in the third direction D3, a portion of the circuit board 2 that overlaps with the bending portions 7 is cut out.

The bending portions 7 extend toward the circuit board 2 from the base portion 3f of the board support member 3. The bending portions 7 extend from the second end portion 3c of the board support member 3. The bending portions 7 are each bent into an L-shape, for example.

The bending portions 7 each have a first portion 7a and a second portion 7b. The first portion 7a is a portion of the bending portion 7 extending along the third direction D3. The first portion 7a extends continuously from the base portion 3f of the board support member 3. The first portion 7a extends from the second end portion 3c of the board support member 3.

The second portion 7b is a portion of the bending portion 7 extending along the first direction D1 from the first portion 7a. The second portion 7b is located outside the second end portion 3c of the board support member 3. With this configuration, the bending portions 7 and the holding arms Sa are engaged with each other.

FIG. 3 is an enlarged cross-sectional view illustrating a region including one of the pressing members 4 of the power converter 1. The pressing members 4 are members that press the electric components A. The electric components A such as the core of the transformer are components that need to be pressed and supported by the pressing members 4.

The pressing members 4 serve as brackets, for example. The pressing members 4 may have elasticity. The pressing members 4 each may be a flat spring, for example. The pressing members 4 may press the electric components A by an elastic force.

The pressing members 4 are located close to the edge portion 2a of the circuit board 2. The pressing members 4 are each located above the circuit board 2. The pressing members 4 each have a plate shape, for example. The pressing members 4 are each made of metal such as stainless steel, for example. The pressing members 4 are each fixed to its associated one of the fixing portions 3a of the board support member 3.

The pressing members 4 each have the fastening portion 4d. The fastening portion 4d is located in a center portion of the pressing member 4. A first through hole 4b for fixing the pressing member 4 to the board support member 3 is formed in the fastening portion 4d. The pressing members 4 are each fixed to the board support member 3 with the screw N inserted through the first through hole 4b. The first through hole 4b is formed with a diameter that allows the screw N to pass through.

In the fastening portion 4d, a plurality of second through holes 4c (two second through holes 4c in the present embodiment) is arranged in a longitudinal direction of each of the pressing members 4 (the first direction D1). A plurality of guide portions 3g (two guide portions 3g in the present embodiment) of the board support member 3 extends through the second through holes 4c.

The guide portions 3g are formed in the upper end 3e of each of the fixing portions 3a of the board support member 3. The guide portions 3g extend upward (in a direction opposite to each of the base portion 3f along the third direction D3) from the upper end 3e. The guide portions 3g each have a stick shape, for example. Before the screw N is fastened, each of the pressing members 4 is positioned on its associated one of the fixing portions 3a by the guide portions 3g. When the screw N is fastened, the guide portions 3g each serve as a rotation stopper.

Each of the pressing members 4 has a pressing portion 4a that extends continuously from the fastening portion 4d in the longitudinal direction thereof. The pressing portion 4a presses at least one of the component used in the power converter 1 or the electric components A against the circuit board 2. The pressing portion 4a presses the core of the transformer against the circuit board 2, for example. The pressing portion 4a is located at an end portion of the pressing member 4 in the longitudinal direction thereof.

As illustrated in FIG. 1, the two pressing members 4 arranged in the first direction D1 may have different shapes. In one of the pressing members 4 located on the other side in the first direction D1 (on a side away from the bending portion 7 in the first direction D1), the pressing portion 4a extends from the fastening portion 4d. Note that the pressing member 4 located on the other side in the first direction D1 presses the core of the transformer.

In the other of the pressing members 4 located on the one side in the first direction D1 (on a side near the bending portion 7 in the first direction D1), a plurality of the pressing portions 4a (two pressing portions 4a in the present embodiment) may extend from the fastening portion 4d. In this case, one of the pressing portions 4a extends in a direction different from the other of the pressing portions 4a, in the present embodiment. Note that the pressing member 4 located on the one side in the first direction D1 presses the core of the reactor.

Refer to FIG. 3 again. A portion of the pressing member 4 located on the other side in the first direction D1 is the held portion 5 in the power converter 1. In the following description, the held portion 5 of the pressing member 4 will be described as an extending portion 6. That is, at least one of the held portions 5 is the extending portion 6.

The extending portion 6 has the same function as that of the bending portion 7. The extending portion 6 is provided on the pressing member 4. The extending portion 6 is located on an end portion opposite to the pressing portion 4a relative to the fastening portion 4d of the pressing member 4. The extending portion 6 extends in an opposite direction to the pressing portion 4a from the fastening portion 4d of the pressing member 4.

The extending portion 6 is formed in one of the pressing members 4, for example. The extending portion 6 is located closer to the edge portion 3d of the board support member 3 than the fixing portion 3a of the board support member 3, which is associated with the one of the pressing members 4, in a plane direction defined by the first direction D1 and the second direction D2. That is, the extending portion 6 is located not on a center side of the board support member 3 but on the side of the edge portion 3d, when viewed in the third direction D3. A distal end portion 6c of the extending portion 6 is located inside the edge portion 3d of the board support member 3.

The extending portion 6 extends in an opposite direction to the circuit board 2 (upward) relative to the fastening portion 4d (that is, the fixed portion) along the third direction D3. The extending portion 6 is bent into an approximately L-shape from the fastening portion 4d of the pressing member 4 and extends upward relative to the circuit board 2. The extending portion 6 includes a first portion 6a and a second portion 6b.

The first portion 6a is a portion of the extending portion 6 extending along the third direction D3. The first portion 6a is adjacent to the fastening portion 4d of the pressing member 4. The first portion 6a is bent at approximately a right angle to the fastening portion 4d of the pressing member 4, for example.

The second portion 6b is a portion of the extending portion 6 extending along the first direction D1. The second portion 6b extends continuously from the first portion 6a. The second portion 6b is located an opposite side to the fastening portion 4d of the pressing member 4 relative to the first portion 6a. The second portion 6b is bent at approximately a right angle to the first portion 6a, for example. The second portion 6b has a rectangular shape, for example, when viewed in the third direction D3.

The second portion 6b is located farther from the circuit board 2 than the fastening portion 4d of the pressing member 4. With this configuration, one of the holding arms Sa is easily inserted into a space between the circuit board 2 and the second portion 6b. The second portion 6b is in contact with the holding arm Sa. The second portion 6b has sufficient strength to be held by the holding arm Sa. In addition, the holding arm Sa is easily inserted into the space between the circuit board 2 and the second portion 6b, so that the space of the power converter 1 may be used efficiently.

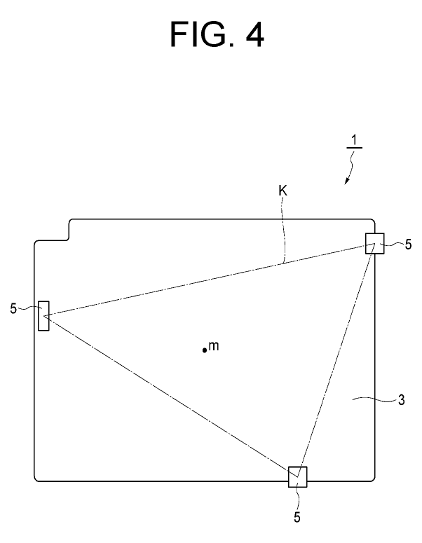

FIG. 4 is a schematic plan view illustrating a plurality of held portions 5 and a center of gravity m of the power converter 1. Outlines of the held portion 5 and the board support member 3 are illustrated in FIG. 4. For example, there are at least three held portions 5. In the present embodiment, the center of gravity m of the power converter 1 is located within an area surrounded by imaginary lines K that connect the three held portions 5. The imaginary lines K are defined as lines imaginarily connecting centers of the respective three held portions 5. The center of gravity m is surrounded by the imaginary lines K.

The imaginary lines K form a polygonal shape (in the present embodiment, a triangular shape). Since the center of gravity m of the power converter 1 is located within the area surrounded by the imaginary lines K, the power converter 1 may be securely hung on the holding arms Sa.

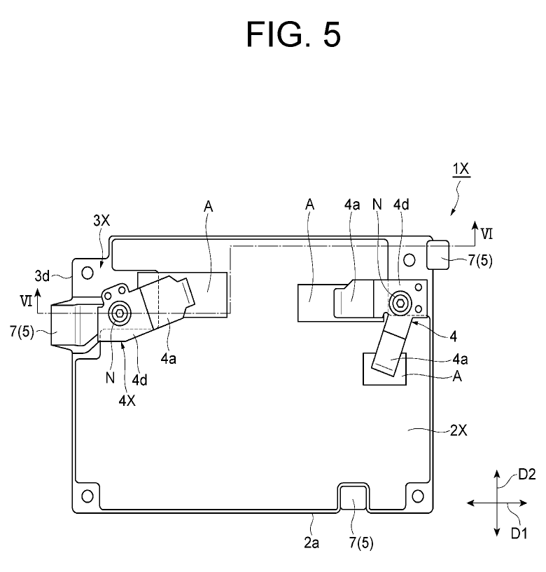

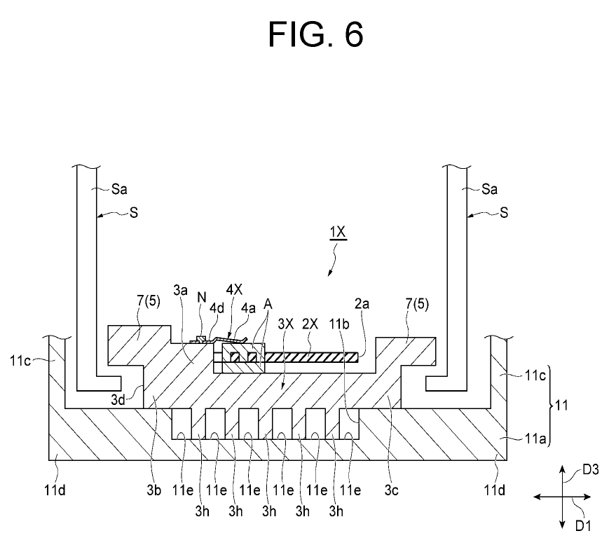

FIG. 5 is a plan view illustrating a power converter according to a comparative example. FIG. 6 is a cross-sectional view taken along a line VI-VI in FIG. 5.

A power converter 1X according to the comparative example is different from the power converter 1 according to the present embodiment in that a pressing member 4X does not have the extending portion 6. The board support member 3X of the power converter 1X is also different from the board support member 3 of the power converter 1 in that the board support member 3X has the held portion 5 serving as the bending portion 7 in place of the extending portion 6. Thus, a shape of a circuit board 2X is also different from the shape of the circuit board 2.

The board support member 3X includes the held portions 5 not only on the second end portion 3c but also on the first end portion 3b. All of the held portions 5 of the power converter 1X, which serve as the bending portions 7, are formed in the board support member 3X. The held portion 5 (the bending portion 7) located on the first end portion 3b is formed integrally with its associated one of the fixing portions 3a and is adjacent to the pressing member 4X. The held portion 5 (the bending portion 7) adjacent to the pressing member 4X extends upward relative to the board support member 3X and has a protruding shape.

As a region occupied by each of the held portions 5 in a case 11 increases, a space for placing the circuit board 2X decreases. As described above, holding arms Sa are movable in three-axial directions, and the held portions 5 need to be formed in the board support member 3X in view of securing a space between the power converter 1X and the case 11. As a result, a space of the circuit board 2X on which the components are placed may be reduced by the area occupied by the held portion 5. The held portion 5, which is only used for mounting the power converter 1X, is preferably designed to occupy as little space as possible.

In the present embodiment, the power converter 1 includes the pressing members 4 each having the pressing portion 4a that presses at least one of the component used in the power converter 1 or the plurality of electric components A against the circuit board 2, and the plurality of the held portions 5 that is engaged with the holding arms Sa of the mounting device S. The board support member 3 has the fixing portions 3a to which the pressing portions 4a of the pressing members 4 are fixed. At least one of the plurality of the held portions 5 is the extending portion 6 formed on one of the pressing portions 4a and located closer to the edge portion 3d of the board support member 3 than the fixing portion 3a, which is associated with the one of the pressing portions 4a. With this configuration, since the at least one of the holding members 5 is the extending portion 6 formed in the pressing member 4, a configuration where the holding arms Sa are engaged with the held portions 5 in the board support member 3 may be reduced. This may reduce a size of the board support member 3. As a result, a space efficiency in the case 11 may be improved. Since the extending portion 6 is located closer to the edge portion 3d of the board support member 3 than the fixing portion 3a, the holding arms Sa of the mounting device S may be easily engaged with the extending portion 6.

In the present embodiment, the extending portion 6 extends in the opposite direction to the circuit board 2 relative to the fastening portion 4d of the pressing member 4. With this configuration, the holding arms Sa of the mounting device S may avoid the electric components A mounted on the circuit board 2 and may be easily engaged with the extending portion 6.

In the present embodiment, the distal end portion 6c of the extending portion 6 is located inside the edge portion 3d of the board support member 3. With this configuration, a space between the extending portion 6 and the board support member 3 may be used efficiently. For example, as illustrated in FIG. 3, the space may be used for a screw N1 with which the circuit board 2 is fixed to the board support member 3 or may be used for the other components.

In the present embodiment, the number of the held portions 5 is at least three, and the center of gravity m of the power converter 1 is located within the area surrounded by the imaginary lines K that connect the at least three of the held portions 5. With this configuration, the power converter 1 may be securely hung by the holding arms Sa of the mounting device S.

In the present embodiment, the electric components A form the core of the transformer or the reactor, and the pressing portion 4a of each of the pressing members 4 presses the core against the circuit board 2. With this configuration, for example, power conversion is efficiently performed by the transformer and power stabilization is achieved by the reactor.

Refer to FIG. 5 again. When the region of the circuit board 2X on which the components are placed are reduced by the area occupied by the held portion 5, it may be impossible to place components to be mounted on the circuit board 2X. As an area of the circuit board 2X on which the components are to be placed increases, an overall configuration of the power converter 1X becomes larger.

In contrast, in the power converter 1 of the present embodiment, the extending portion 6 is formed in its associated one of the pressing members 4, so that a space for the held portions 5 formed in the board support member 3X may be used for the circuit board 2. This may reduce a size of the power converter 1.

In addition, a configuration corresponding to the held portions 5 may be omitted from the board support member 3, which may reduce a material for forming the board support member 3. Thus, a manufacturing cost of the board support member 3 may be reduced. In the board support member 3 from which the configuration is omitted, subjects to be inspected are reduced, so that a quality verification becomes easier.

The configuration of the board support member 3 may be simplified, thereby reducing a weight of the board support member 3. Since the configuration corresponding to the held portions 5 may be omitted from the board support member 3, the board support member 3 may be manufactured easily.

In a manufacturing process of the board support member 3, the materials for forming the board support member 3 may be cooled. When a thickness of the board support member 3 is uneven, a temperature of the board support member 3 in the manufacturing process also may become uneven. In this case, the material of a portion of the board support member 3 having a protruding shape, such as the held portions 5 may fail to harden, which may result in a seizure. Thus, the board support member 3X that includes a lot of the held portions 5 may be reduced in quality.

In addition, when the board support member 3X is formed with a mold, a shape of the board support member 3X becomes more complex because of the held portions 5, so that high pressure is required to be applied to the mold. Thus, equipment that is capable of applying high pressure may be required, which may increase the manufacturing cost of the board support member 3X.

In the board support member 3 of the present embodiment, some of the held portions 5 are omitted, so that the seizure of the board support member 3 may be suppressed, and the board support member 3 of the present embodiment may maintain the quality. In addition, the board support member 3 need not be formed with high pressure, which may reduce the manufacturing cost of the board support member 3.

Although the embodiment of the present disclosure has been described; however, the present disclosure is not limited to the above-described embodiment. In the above-described embodiment, for example, the extending portion 6 is formed in the one of the plurality of the pressing members 4; however, the present disclosure is not limited thereto. For example, the extending portion 6 may be formed in all of the pressing members 4.

In the above-described embodiment, the extending portion 6 extends in the opposite direction to the circuit board 2 relative to the fastening portion 4d of the pressing member 4 in the third direction D3; however, the present disclosure is not limited thereto. For example, the extending portion 6 may extend toward the circuit board 2 relative to the pressing portion 4a of the pressing member 4 or may extend in a flush manner with the fastening portion 4d of the pressing members 4.

In the above-described embodiment, the grooves 11e are formed in the upper portion of the bottom portion 11a of the case 11; however, the present disclosure is not limited thereto. For example, instead of the grooves 11e serving as the water passages, an air cooling fan may be provided in the upper portion, on, or above the bottom portion 11a of the case 11.

In the above-described embodiment, the power converter 1 is accommodated in the case 11 as the mounting target; however, the present disclosure is not limited thereto. For example, the mounting target may be formed in an approximately flat shape without a wall such as the side wall portion 11c, or the mounting portion may be surrounded by the other components.

In the above-described embodiment, the power converter 1 is accommodated only in the case 11; however, the present disclosure is not limited thereto. For example, the power converter 1 accommodated in the case 11 may be further accommodated in another case. The case has a box shape. A capacity of the case is larger than a capacity of the case 11. The power converter 1 accommodated in the case 11 is surrounded by a wall portion of the case. An example of the case is a T/A case (transaxle case). The case may be mounted on a vehicle, for example.

In the above-described embodiment, the extending portion 6 is formed in the pressing member 4, which presses the core of the transformer that is the winding C disposed on the front surface or the back surface of the circuit board 2, or formed in the inner layer of the circuit board 2; however, the present disclosure is not limited to a configuration in which the winding C is disposed as the transformer in the circuit board 2. For example, the extending portion 6 may be formed in the pressing member 4 that presses the core of the transformer formed of a coil having a plate shape or a line shape, the coil being provided separately from the circuit board 2. The pressing member 4 may press the core of the reactor. In this case, both cores of the transformer and the reactor are the components used in the power converter 1.

In the above-described embodiment, the pressing portion 4a presses the core of the transformer as the electric components A against the circuit board 2; however, the present disclosure is not limited to the embodiment. The pressing portion 4a may press components other than the core of the transformer, which are mounted on the circuit board 2, as the electric components A against the circuit board 2.

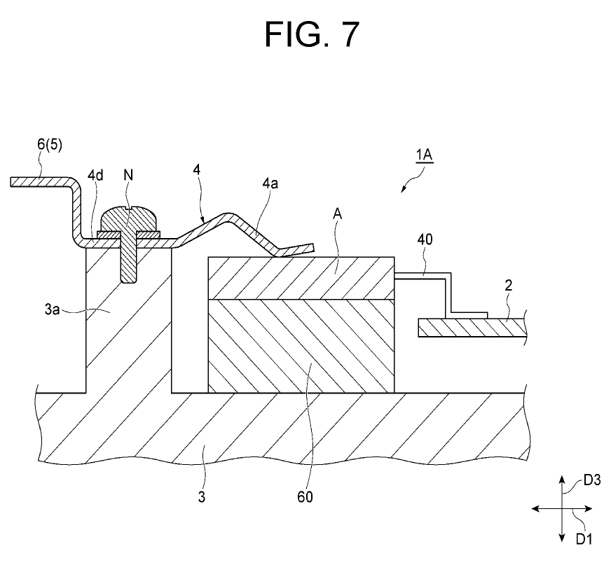

For example, the pressing portion 4a may press a heating element against the circuit board 2. FIG. 7 is an enlarged cross-sectional view illustrating a power converter 1A according to a modification of the present disclosure. In the power converter 1A, the heating element is provided as the electric components A mounted on the circuit board 2. In the power converter 1A, a heat releasing body 60 is provided between the heating element and the board support member 3. The heat releasing body 60 may be formed integrally with the board support member 3. A lead 40 of the heating element extends to the circuit board 2 and is soldered to a wiring, which is not illustrated, formed on the circuit board 2.

The heat releasing body 60 is located on the board support member 3. The heat releasing body 60 is located on an end portion of the power converter 1A in the first direction D1. The heat releasing body 60 is adjacent to the fixing portion 3a of the board support member 3 in the first direction D1. As illustrated in FIG. 7, the pressing portion 4a may press the heating element against the circuit board 2 together with the heat releasing body 60.

What is claimed is:

1. A power converter mounted on a mounting target by a mounting device, the power converter comprising:
a circuit board on which a plurality of electric components is mounted;
a board support member that supports the circuit board;
a pressing member having a fixed portion that is fixed to the board support member and a pressing portion that presses at least one of a component used in the power converter or the plurality of the electric components against the circuit board; and
a plurality of held portions that is each engaged with a holding arm of the mounting device, wherein
at least one of the plurality of the held portions is an extending portion that is formed in the pressing member,
the board support member has a fixing portion to which the pressing portion is fixed, and
the extending portion is located closer to an edge portion of the board support member than the fixing portion.

2. The power converter according to claim 1, wherein
the extending portion extends in an opposite direction to the circuit board relative to the fixed portion.

3. The power converter according to claim 1, wherein
a distal end portion of the extending portion is located inside the edge portion of the board support member.

4. The power converter according to claim 1, wherein
the plurality of the held portions is at least three of the held portions, and
a center of gravity of the power converter is located within an area surrounded by imaginary lines that connect the at least three of the held portions.

5. The power converter according to claim 1, wherein
the component is a core of a transformer or a reactor, and
the pressing portion presses the core against the circuit board.
